(19) United States
(12) Patent Application Publication
(10) Pub. No.: US 2026/0334117 A1
(43) Pub. Date: Oct. 22, 2026

(54) METHOD FOR ETCHING SEMICONDUCTOR DEVICE

(71) Applicant: Tokyo Electron Limited, Tokyo (JP)

(72) Inventor: Scott Lefevre, Albany, NY (US)

(21) Appl. No.: 19/095,208

(22) Filed: Mar. 31, 2025

(51) Int. Cl. H01L 21/3065; H01L 21/265; H01L 21/308; H01L 21/3213

(52) U.S. Cl. CPC H10P 50/242; H10P 30/204; H10P 30/21; H10P 50/268; H10P 50/695; H10P 50/71

(57) ABSTRACT

A method is provided for etching a substrate. The method includes loading a substrate in a process chamber. The substrate includes a patterned mask layer disposed over a layer to-be-etched. Ions are implanted into the layer to-be-etched through openings in the patterned mask layer to form an implanted region. After the implanting, a plasma including fluorine is generated. The substrate is exposed to the plasma to etch the implanted region. The implanted ions act as catalysts that enhance the etching rate in the implanted region compared to non-implanted regions.

### TECHNICAL FIELD

The present invention relates generally to a method for semiconductor processing and, in particular embodiments, to a method for etching a semiconductor device.

### BACKGROUND

In semiconductor device fabrication, etching processes are fundamental for creating various device structures and features. These processes involve selectively removing material from a substrate through chemical and/or physical interactions. Many etching steps are performed using plasma processes, where the plasma generates reactive species that chemically react with the material to be removed. The etch rate and selectivity are heavily dependent on the chemistry of the etchant gases used in the plasma.

As semiconductor devices continue to scale down to nanometer dimensions, precise control over etch profiles and rates becomes increasingly critical. The semiconductor industry faces the challenge of maintaining high etch performance while transitioning to more environmentally sustainable processes. This is particularly crucial for fabricating advanced three-dimensional structures, such as fin field-effect transistors (FinFETs), where precise control over etch profiles and rates is essential. Meeting these technical requirements while addressing environmental concerns requires innovation in both process chemistry and etch techniques.

### SUMMARY

In accordance with one aspect of the present invention, a method is provided for etching a substrate. The method includes loading a substrate in a process chamber, wherein the substrate comprises a patterned mask layer disposed over a layer to-be-etched. Ions are implanted into the layer to-be-etched through openings in the patterned mask layer to form an implanted region. After the implanting, a plasma comprising fluorine is generated. The substrate is exposed to the plasma to etch the implanted region.

In accordance with another aspect of the present invention, a method is provided for etching a substrate. The method includes exposing a substrate to ion implantation, wherein the substrate comprises a patterned mask layer disposed over a layer to-be-etched, and the ion implantation forms an ion implanted region in the layer to-be-etched through openings in the patterned mask layer. A first etching process is performed by exposing the ion implanted regions to a first plasma. After the first etching process, a second etching process is performed by exposing the layer to-be-etched to a second plasma, wherein the second etching process further etches the layer to-be-etched through the openings in the patterned mask layer.

In accordance with yet another aspect of the present invention, a method is provided for etching a substrate. The method includes loading a substrate in a process chamber, wherein the substrate comprises a first patterned mask layer disposed over a layer to-be-etched. Ions are implanted at a first beam energy into the layer to-be-etched to form a first ion implanted region. A second patterned mask layer is formed over the layer to-be-etched. A plasma comprising fluorine is generated. The layer to-be-etched is exposed to the plasma to etch the first ion implanted region through the second patterned mask layer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1D illustrate cross-sectional views of a method for etching a substrate using ion implantation followed by etching process, in accordance with an embodiment;

FIGS. 2A-2C illustrate experimental data demonstrating the catalytic effects of sulfur during etching processes, in accordance with an embodiment;

FIGS. 3A-3C illustrate cross-sectional views of a method for etching a substrate using multiple-stage ion implantation, in accordance with an embodiment;

FIGS. 4A-4C illustrate cross-sectional views of a method for etching a substrate using a combination of different plasma, in accordance with an embodiment;

FIGS. 5A-5E illustrate cross-sectional views of a method for achieving different etch rates through selective ion implantation, in accordance with an embodiment;

FIG. 6 illustrates a cross-sectional view of a method for selective ion implantation with different depths and concentrations for controlled differential etching, in accordance with an embodiment;

FIG. 7 illustrates a process flow diagram for a method of implanting sulfur and etching a substrate, in accordance with an embodiment; and

FIG. 8 illustrates a process flow diagram for a method of etching different features with controlled etch rates, in accordance with an embodiment.

### DETAILED DESCRIPTION OF ILLUSTRATIVE EMBODIMENTS

Silicon etching is a critical process in semiconductor device fabrication. Sulfur hexafluoride (SF₆) has traditionally been the preferred etchant gas due to high silicon etch rates and process stability. However, SF₆ has several environmental concerns as it can remain in the atmosphere for extended periods.

Various embodiments described herein provide methods for achieving enhanced silicon etch rates while eliminating or reducing the use of sulfur-based gases like SF₆. The methods utilize sulfur ion implantation to introduce catalytic sulfur directly into targeted regions of the silicon containing layer, followed by etching with fluorine-containing gases. For example, nitrogen trifluoride (NF₃), or fluorine (F₂) and hydrogen fluoride (HF), may be used as alternative etchant gases while maintaining high etch rates.

In various embodiments, the sulfur ion implantation process may provide precise control over the catalyst placement and concentration. This enables independent control of etch rates and profiles in different regions of the substrate. The implantation depth and dose may be tightly controlled to enhance etching in specific locations while maintaining original etch characteristics elsewhere. This selective enhancement is particularly beneficial for smaller features where profile control is critical.

The implantation of sulfur catalyst may provide a wider availability of process gases to be used for etch, eliminating the need to modify gas box of existing etch tool. Additionally, partial implantation techniques may be used to avoid enhanced etching in certain portions of features, reducing unwanted effects like bow and undercut that can occur with conventional SF6-based processes. In various embodiments, the combination of sulfur ion implantation and lower-GWP etch gases may enable reduced environmental impact while maintaining or improving etch performance. This particularly benefits etching of profile-sensitive features where conventional SF₆ processes may produce undesirable isotropic characteristics or surface roughness.

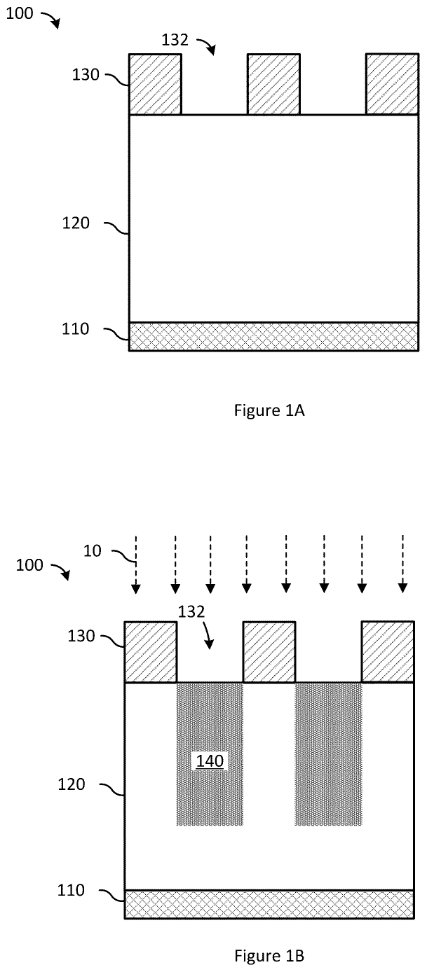

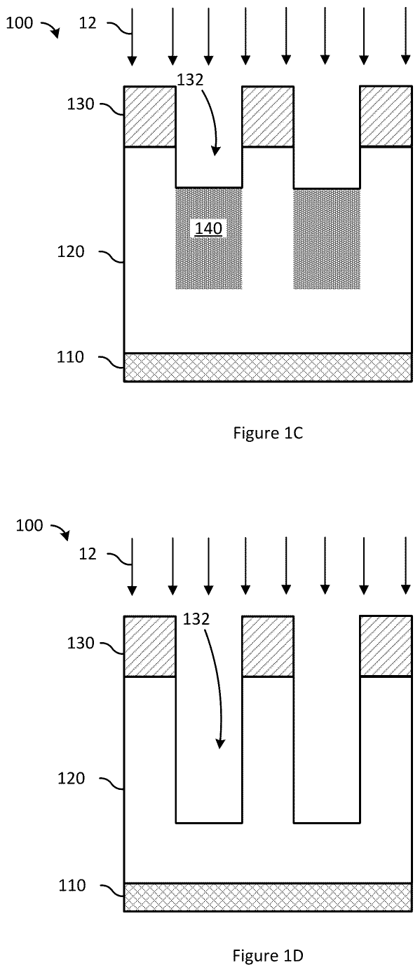

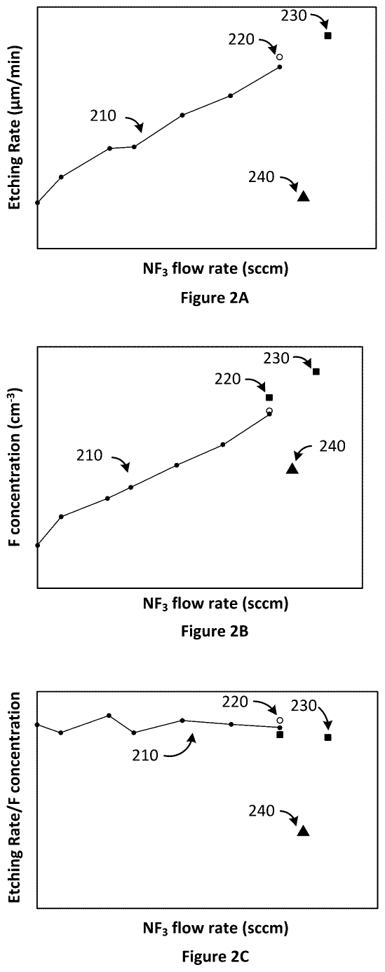

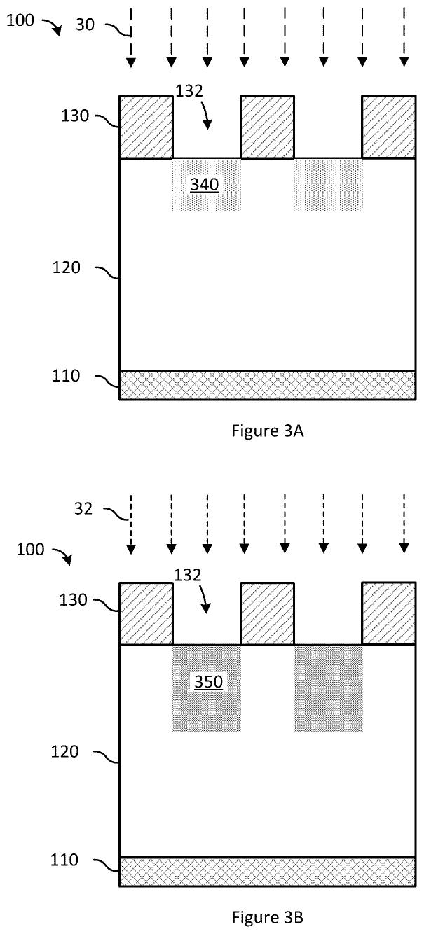

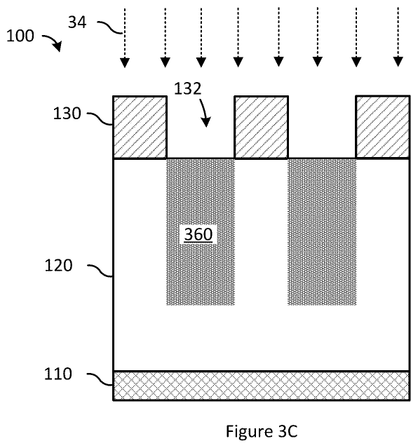

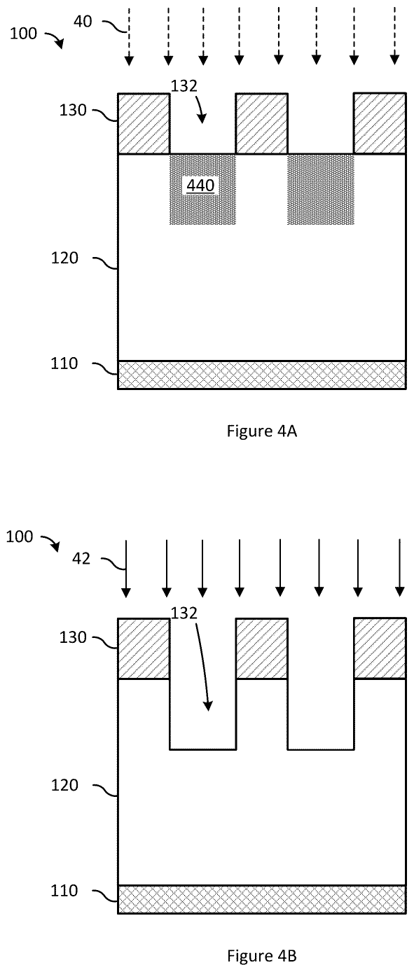

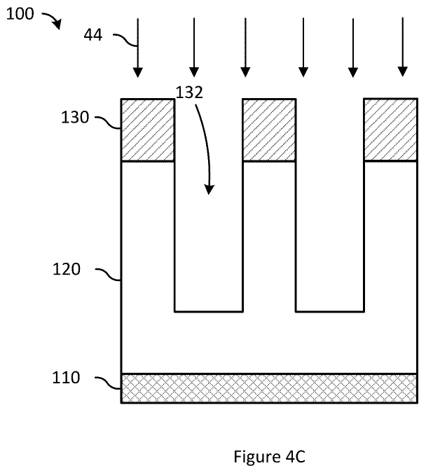

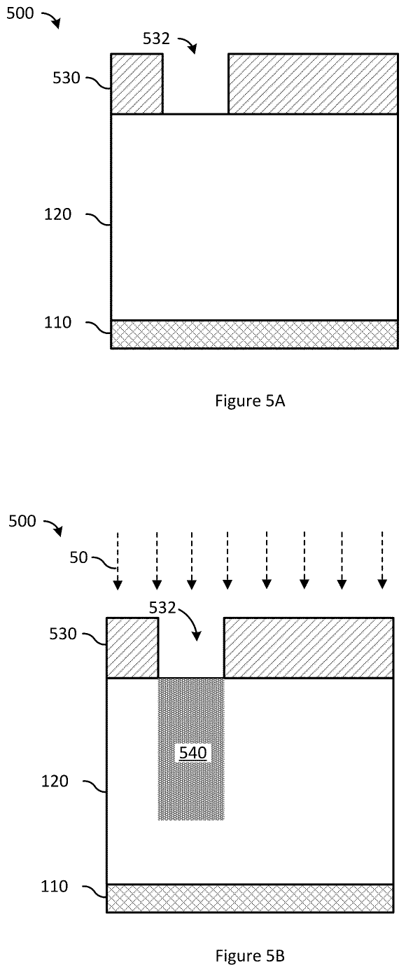

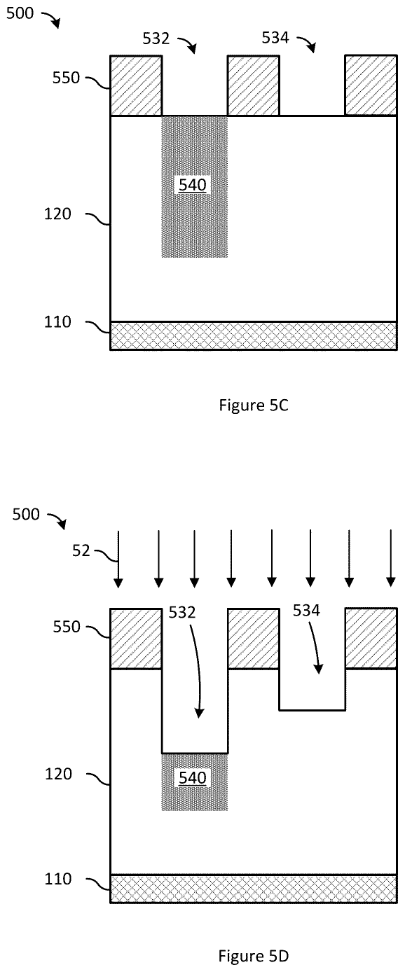

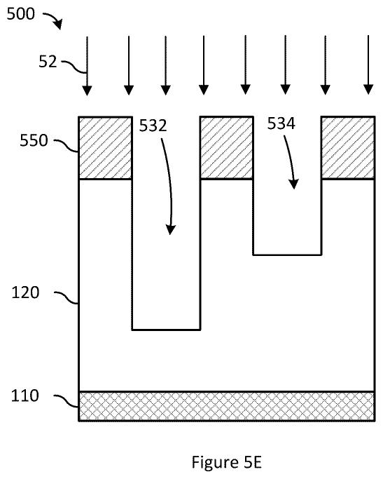

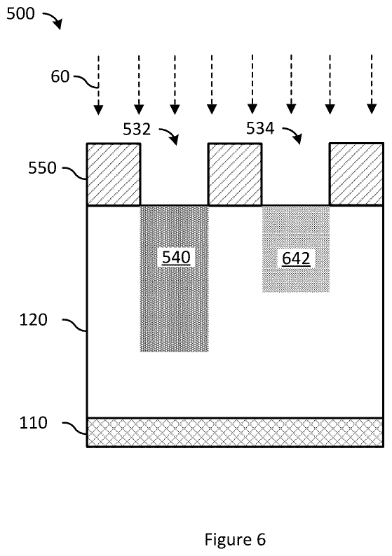

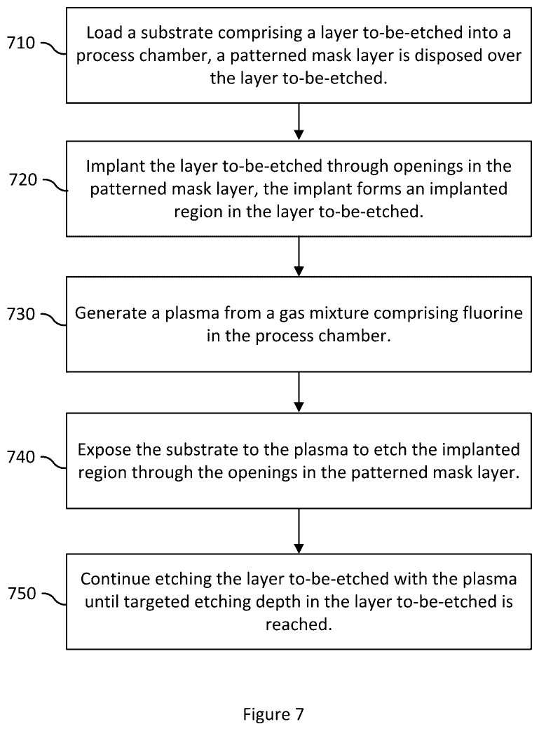

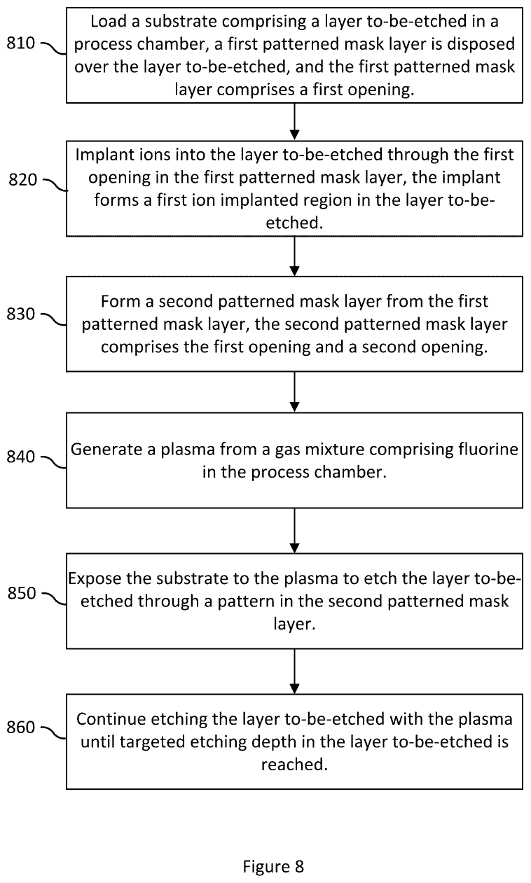

Embodiments of the disclosure are described in the context of the accompanying drawings. An embodiment of a process flow for ion implantation followed by plasma etching is described using FIGS. 1A-1D. Experimental data demonstrating sulfur catalytic effects during etching are illustrated in FIGS. 2A-2C. A variation of the implantation process using multiple implantation stages is shown in FIGS. 3A-3C. A second embodiment combining non-SF₆ and SF₆ plasma etching is described using FIGS. 4A-4C. A third embodiment for achieving different etch rates through selective sulfur implantation is illustrated in FIGS. 5A-5E. A variation of selective implantation with different depths and concentrations is shown in FIG. 6. Process flow diagrams for different etching processes are presented in FIGS. 7 and 8.

FIGS. 1A-1D illustrate cross sectional views of a process flow for ion implantation followed by plasma etching, in accordance with an embodiment.

In FIG. 1A, a substrate 100 may be loaded in a process chamber. In various embodiments, the substrate 100 may comprise a substrate layer 110, a layer to-be-etched 120 disposed over the substrate layer 110, and a patterned mask layer 130 disposed over the layer to-be-etched 120.

The process chamber, in various embodiments, may be an implanting chamber configured to perform ion implantation. The implanting chamber may comprise an ion source for generating sulfur ions, an acceleration column for directing the ions toward the substrate 100, and a substrate holder for supporting and positioning the substrate 100 during implantation. In various embodiments, the implanting chamber maintains vacuum conditions and includes mechanisms for controlling implant parameters such as ion energy, dose, and angle of implantation. The chamber may include beam scanning capabilities to ensure uniform implantation across a surface of the substrate 100.

In one or more embodiments, the substrate layer 110 may be a silicon wafer, or a silicon-on-insulator (SOI) wafer. In certain embodiments, the substrate layer 110 may comprise silicon germanium, silicon carbide, gallium arsenide, gallium nitride, or other compound semiconductors. In other embodiments, the substrate layer 110 may comprise heterogeneous layers such as silicon germanium on silicon, gallium nitride on silicon, silicon carbon on silicon, as well layers of silicon on a silicon or SOI substrate. In various embodiments, the substrate layer 110 may be patterned or embedded in other components of the semiconductor device.

In various embodiments, although not illustrated, the substrate layer 110 may further comprise various layers useful for semiconductor device fabrication, which may be collectively regarded as a part of the substrate layer 110 in this disclosure. For example, in certain embodiments, over the substrate layer 110, there may be a dielectric layer comprising a silicon-based dielectric material with a low dielectric constant (i.e., low-k value) such as organosilicate glass (SiCOH), dense SiCOH, porous SiCOH, and other porous dielectric materials.

In various embodiments, the layer to-be-etched 120 may comprise silicon or silicon-containing materials to be etched. The layer to-be-etched 120 may include single-crystal silicon, polycrystalline silicon, amorphous silicon, or silicon-containing compounds. In an embodiment, the thickness of the layer to-be-etched 120 may range from 5 nanometers to several micrometers.

In one or more embodiments, the patterned mask layer 130 may comprise openings 132 that expose portions of the underlying layer to-be-etched 120. The patterned mask layer 130 may serve as an implant mask and an etch mask in subsequent processing steps. In various embodiments, the patterned mask layer 130 may comprise materials resistant to both ion implantation and plasma etching, such as silicon oxide, silicon nitride, or hardened photoresist. The thickness of the patterned mask layer 130 may be selected to withstand both the implantation and etching processes while maintaining critical dimensions of the openings 132. In some embodiments, the depth of the patterned mask layer 130 may range from 5 nm to 100 nm.

The openings 132 in the patterned mask layer 130 may have various geometries and dimensions depending on the device structures being formed. In various embodiments, the openings 132 may have widths ranging from tens to hundreds of nanometers. The sidewalls of the openings 132 may be substantially vertical to facilitate directional ion implantation and subsequent anisotropic etching processes. Multiple openings 132 may be formed across the substrate surface with different dimensions or spacing to create various device features.

In various embodiments, the patterned mask layer 130 may be formed through a lithography process. In various embodiments, the process may include depositing a mask material over the layer to-be-etched 120, forming a pattern in the mask material using photolithography, and etching the mask material through the pattern to form the openings 132. The etching may comprise dry etching, wet etching, or a combination thereof to achieve desired profile control of the openings 132.

In some embodiments, the patterned mask layer 130 may comprise a metal oxide resist comprising hafnium oxide, zirconium oxide, titanium oxide, or combinations thereof. In some embodiments, the metal oxide resist may be formed by spin-coating a metal-containing precursor solution onto the layer to-be-etched 120, followed by a baking process to remove solvents and form metal-oxygen bonds. In various embodiments, the precursor solution includes metal alkoxides, metal halides, or metal organic compounds dissolved in suitable solvents. In various embodiments, the baking temperature may range from 100 °C to 300 °C.

In other embodiments, the metal oxide resist may be formed using vapor deposition techniques such as chemical vapor deposition (CVD), atomic layer deposition (ALD), or plasma-enhanced versions thereof. In one example, the metal oxide resist may be formed through CVD processes using precursors such as metal halides, metal alkoxides, or metalorganics to react with oxidizing agents like water vapor, oxygen, or ozone. In another example, the metal oxide resist may be formed through ALD processes, where the metal oxide is formed through sequential, self-limiting surface reactions using similar precursors. In various embodiments, the deposition temperature may range from 100 °C to 500 °C.

In one or more embodiments, the metal oxide resist may be patterned using various lithography techniques. In an embodiment, the patterning may use electron beam lithography or extreme ultraviolet lithography, followed by development to form the openings 132. In various embodiments, the development process may comprise wet development using alkaline solutions, dry development using reactive gases, or plasma development. In various embodiments, the wet development may use tetramethylammonium hydroxide (TMAH) or other alkaline developers. The dry development may use halogen-containing gases such as chlorine, hydrogen bromide, or fluorine-containing species. The plasma development may use oxygen-based, hydrogen-based, or halogen-based plasmas.

In alternative embodiments, the patterned mask layer 130 may comprise organic photoresist materials, which may include positive-tone or negative-tone resist materials such as phenol formaldehyde resin, polyhydroxystyrene derivatives, or chemically amplified resists. The photoresist layer may be formed by spin-coating followed by a soft bake at temperatures between 90 °C to 150 °C. The pattern may be formed by exposing the photoresist to ultraviolet radiation through a photomask, performing a post-exposure bake, and developing in an appropriate developer solution. In various embodiments, the photoresist may undergo a hardening process such as UV curing or thermal reflow to enhance its resistance to subsequent implantation and etching processes.

FIG. 1B illustrates an ion implantation process performed on the substrate 100, where an ion flux 10 may be implanted into the substrate 100. In various embodiments, the ion flux 10 may comprise different types of ions such as boron, phosphorus, arsenic, nitrogen, oxygen, sulfur, germanium, silicon, or the like. In an embodiment, the ion flux 10 may comprise sulfur ions which may be implanted into the layer to-be-etched 120 through the openings 132 in the patterned mask layer 130.

The sulfur ion implantation process (or referred to as the implanting) may begin with introducing a sulfur-containing source material into an ion source. In various embodiments, the sulfur-containing source material may comprise solid sulfur, hydrogen sulfide (H₂S), or sulfur fluoride compounds. The ion source may ionize the sulfur-containing source material to generate sulfur ions using techniques such as electron impact ionization, microwave excitation, or radio frequency excitation. The generated sulfur ions may be then accelerated toward the substrate 100 through an acceleration column.

During the implantation process, the accelerated sulfur ions may penetrate the exposed portions of the layer to-be-etched 120 through the openings 132, forming ion implanted regions 140. In various embodiments, an ion implanted region may also be referred to as an implanted region. In various embodiments, the patterned mask layer 130 may block the sulfur ions from reaching covered portions of the layer to-be-etched 120, resulting in selective formation of the ion implanted regions 140. The depth and concentration profile of the ion implanted regions 140 may be controlled by adjusting implantation parameters such as ion beam energy and ion dose. In an embodiment, the implantation energy may range from 10 keV to 200 keV, and the implantation dose may range from 10¹³ to 5×10¹⁶ ions/cm², for example, 5×10¹³ to 10¹⁶ ions/cm². In some embodiments, the ion implanted regions 140 may comprise a depth of 10 nm to 100 nm with a sulfur concentration of 10¹⁸ cm⁻³ to 10²¹ cm⁻³.

The ion implanted regions 140 may serve as catalytic regions that enhance subsequent etching processes. In various embodiments, the substrate 100 may be tilted at an angle relative to the direction of the implanted ions to control the implant profile and minimize channeling effects. The implantation process may be performed at temperatures ranging from −40 °C to 400 °C to control diffusion of the implanted species.

FIGS. 3A-3C illustrate a variation of the sulfur ion implantation process using multiple implantation stages. The multiple implantation stages may comprise performing a plurality of implants at different beam energies to form a graded implanted ion concentration profile in the layer to-be-etched 120. This staged implantation approach may provide enhanced control over the concentration profile and depth distribution of sulfur ions within the layer to-be-etched 120.

FIG. 3A shows a first implantation stage (or referred to as a first implant) where sulfur ions 30 are implanted into the layer to-be-etched 120 through openings 132, forming initial ion implanted regions 340. In various embodiments, the first implant may use a first beam energy and a first dose to establish an initial implant profile.

FIG. 3B illustrates a second implantation stage (or referred to as a second implant) performed on the same substrate, modifying the implanted regions to form implantation regions 350 with an adjusted concentration profile. The second implant may generate sulfur ions 32 using a second beam energy different from the first beam energy and a second dose different from the first dose. In various embodiments, the cumulative dose from both implants creates a graded concentration profile in the ion implanted regions 350.

FIG. 3C shows a third implantation stage (or referred to as a third implant) further modifying the implanted regions to form implanted regions 360 with a final concentration profile. The third implant may generate sulfur ions 34 using a third beam energy and dose to fine-tune the sulfur distribution in the implanted regions. In various embodiments, the plurality of implants may provide better control over the catalytic effect at different depths to accommodate customized or more complex etch requirements. The ion implantation process using the plurality of implants may create graded concentration profiles for more uniform etch rates.

In various embodiments, the beam energy levels may range from 10 keV to 1 MeV across the different implants, with each subsequent implant using different beam energy levels to target specific depths. The dose at each implant may be adjusted between from 10¹⁴ to 10¹⁶ ions/cm² to achieve desired concentration profiles. The combination of different energies and doses across multiple implants enables precise control over the final sulfur distribution profile.

In various embodiments, after the ion implantation process, shown in FIG. 1B or FIGS. 3A-3C, the substrate 100 may undergo a thermal annealing process. In various embodiments, the annealing temperature may range from 100 °C to 500 °C. The annealing may be performed using different techniques such as rapid thermal processing (RTP), furnace annealing, flash lamp annealing, or laser annealing. The duration of the annealing process may range from several seconds in RTP to several minutes in furnace processing. The thermal annealing may repair potential crystal damage caused by the implantation process, and promote diffusion of the implanted ions (e.g., sulfur) to desired lattice sites. In an embodiment, the annealing process may be performed in various ambient environments including inert gases such as nitrogen, argon, or forming gas, or reactive gases such as oxygen or hydrogen, depending on the desired effects on the implanted regions.

In various embodiments, FIG. 1C illustrates a plasma etching process performed on the substrate 100 after the ion implantation process. In some embodiment, the substrate 100 may be transferred from the process chamber to an etching chamber configured for etching process to perform the plasma etching. In alternative embodiment, the substrate 100 may remain in the same process chamber for both ion implantation and plasma etching. The process chamber may be configured with dual-mode capabilities to perform both processes. In various embodiments, the chamber may include an ion source and acceleration column for implantation, as well as RF power delivery systems and gas distribution components for plasma generation. The chamber may be equipped with switchable power supplies that can operate in either implant mode using high voltage for ion acceleration or plasma mode using RF power for plasma generation. A dual-mode gas delivery system accommodates both sulfur-containing source gases for implantation and fluorine-containing gases for etching. In various embodiments, the substrate support may include temperature control capabilities suitable for both processes, and can be configured for both precise implant angle control and bias power application during etching. The dual-mode capabilities of process chamber may help reduce potential contamination and oxidation during exposing the surface to atmosphere upon substrate transfer.

In various embodiments, etching gases may be flowed into the process chamber through gas distribution components. The etching gases may comprise fluorine-containing gases such as fluorine, nitrogen fluoride, hydrogen fluoride, fluorocarbon, or the like. In various embodiments, the fluorocarbon may comprise carbon tetrafluoride (CF₄), tetrafluoroethylene (C₂F₄), hexafluoroethane (C₂F₆), octafluoropropane (C₃F₈), other CₓF_{y} compounds, or partially fluorinated hydrocarbons such as trifluoromethane (CHF₃), 1,1,1,2-tetrafluoroethane (C₂H₂F₄), or other hydrofluorocarbons. In an embodiment, the flow rate of the etching gases may range from 10 sccm to 1000 sccm. Additional gases such as argon, helium, or nitrogen may be added as carrier or dilution gases.

In one or more embodiments, a plasma 12 may be generated by applying radio frequency (RF) power to the etching gases through one or more RF power sources. In various embodiments, a source RF power ranging from 50 W to 5000 W may be applied at frequencies between 1 kHz and 100 MHz to create and sustain the plasma. The RF power ionizes the gas mixture to form reactive fluorine species that participate in the etching process. The plasma density and composition may be controlled by adjusting the RF power level and gas flow rates.

In various embodiments, a bias RF power may be applied to the substrate support. In some embodiments, the bias power may range from 0 to 25 kW at frequencies between 1 kHz and 100 MHz, creating a potential difference that directs ions toward the substrate surface. The bias power may control ion bombardment energy, which affects etch directionality and rate. The combination of source power and bias power enables independent control of plasma density and ion energy for optimized etch performance.

In various embodiments, process parameters such as chamber pressure, temperature, and power levels may be maintained within specific ranges during the etching process. In an embodiment, the chamber pressure may range from 1 mTorr to 1000 mTorr. The substrate temperature may be controlled between 0 °C and 200 °C using substrate support temperature control systems.

Upon exposing the substrate 100 to the plasma, reactive fluorine species from the plasma may react with the layer to-be-etched 120 through the openings 132 in the patterned mask layer 130. The exposing may etch the implanted regions 140 in the layer to-be-etched 120. In various embodiments, the fluorine radicals and ions generated in the plasma may diffuse to the surface and chemically react with silicon atoms in the layer to-be-etched 120 to form volatile silicon fluoride compounds that desorb from the surface.

The presence of implanted sulfur in the ion implanted regions may catalytically enhance the etching process. In various embodiments, the sulfur atoms in the ion implanted regions 140 and 360 may modify the local chemical environment and facilitate the reaction between fluorine species and silicon. As a result of this catalytic effect, the ion implanted regions 140 may exhibit higher etch rates compared to non-implanted regions. This catalytic mechanism allows for efficient etching using fluorine-containing gases with lower global warming potential compared to conventional SF₆-based processes.

FIG. 1D illustrates the continuation of the plasma etching process until a targeted depth in the layer to-be-etched 120 is reached. During this extended etching period, the reactive fluorine species from the plasma continue to react with the layer to-be-etched 120 through the openings 132. In various embodiments, the ion implanted regions 140 maintain their catalytic effect throughout the etching process, promoting sustained enhanced etch rates in these regions.

The etching process may be monitored and controlled using various endpoint detection techniques. In various embodiments, optical emission spectroscopy may be used to monitor the presence of reaction products in the plasma, indicating the progression of the etch process. Other techniques such as laser interferometry or bias voltage monitoring may also be employed to determine when the targeted etch depth is achieved.

In various embodiments, the enhanced etch rate in the implanted regions 140 contributes to more vertical sidewall profiles compared to conventional processes. The selective placement of sulfur through implantation helps minimize lateral etching and reduce unwanted effects such as bowing or undercut. The etch depth uniformity across the substrate 100 may be controlled by the initial sulfur implant distribution and plasma process parameters.

After reaching the targeted etch depth, the plasma etching process may be terminated. In various embodiments, the substrate 100 may undergo subsequent cleaning or treatment steps to remove residual etch products or prepare the surface for further processing. The patterned mask layer 130 may be removed using appropriate stripping processes if no longer needed for subsequent processing steps.

In various embodiments, the processes illustrated in FIGS. 1B through 1D may be performed cyclically, alternating between ion implantation and plasma etching steps until reaching the targeted depth. Each cycle may comprise a controlled-depth ion implantation followed by a defined period of plasma etching. In an embodiment, the implantation energy in each cycle may be adjusted to position sulfur at optimal depths for the subsequent etch step, while the etching time in each cycle may be controlled to remove a specific thickness of material. The shorter process steps in each cycle may provide better control over feature profiles compared to extended single-step processing. In various embodiments, process parameters such as beam energy, dose, and etch duration may be individually optimized for each cycle to achieve desired profile control and etch characteristics. The number of cycles may be determined based on the total target depth and the depth increment per cycle.

FIGS. 2A-2C present experimental data demonstrating the catalytic effect of sulfur during silicon etching, in accordance with an embodiment. The data compares different process conditions: curve 210 represents etching with a gas mixture comprising NF₃ and SF₆, curves 220 and 230 show results at elevated temperatures of 30 °C and 10 °C respectively, and curve 240 shows results after removing SF₆ from the gas mixture.

FIG. 2A illustrates the etch rate behavior under these conditions as a function of NF₃ flow rate. In various embodiments, the etch rate increases with higher NF₃ flow rate and maintains high values with SF₆ present in the gas mixture (curves 210, 220, 230). However, as shown by curve 240, the etch rate drops significantly when SF₆ is removed from the gas mixture.

FIG. 2B shows the fluorine concentration measurements under the same conditions. In various embodiments, the fluorine concentration remains relatively stable across all conditions, including after SF₆ removal (curve 240). The sustained fluorine concentration indicates that the availability of fluorine species alone cannot explain the observed drop in etch rate when SF₆ is removed.

FIG. 2C shows the etch rate normalized by fluorine concentration, effectively showing the etch yield per available fluorine species. In various embodiments, curves 210, 220, and 230 show consistent etch efficiency when SF₆ is present. However, curve 240 shows a rapid decrease in etch efficiency after SF₆ removal, despite the presence of fluorine species. This data supports that sulfur may act as a catalyst in the etching process, enhancing the reaction efficiency between fluorine and silicon. The results demonstrate that maintaining high etch rates requires either SF₆ in the gas mixture or, as presented in the current disclosure, pre-implanted sulfur in the regions to be etched.

FIGS. 4A-4C illustrate cross sectional views of an etching process with a partial ion implantation, in accordance with an embodiment. Components and features in FIGS. 4A-4C that share reference numbers with those in FIGS. 1A-1D have corresponding structures and operations as previously described.

In one or more embodiments, FIG. 4A illustrates an ion implantation process by exposing the substrate 100 to an ion flux 40. Similar to the implantation process described in FIG. 1B, the ions may be implanted into the layer to-be-etched 120 through openings 132 in the patterned mask layer 130, forming ion implanted regions 440. The ion implanted regions 440 may be intentionally limited to the upper portion of the region to be etched in the layer to-be-etched 120.

In various embodiments, the ion implantation process may utilize similar ions, parameters and conditions as described for the ion implantation process in FIGS. 1B and 3A-3C. The sulfur-containing source material may comprise solid sulfur, hydrogen sulfide (H₂S), or sulfur fluoride compounds. The implantation energy may range from 10 keV to 200 keV, and the implantation dose may range from 10¹⁴ to 10¹⁶ ions/cm₂. The substrate 100 may be tilted at an angle relative to the direction of the implanted ions to control the implant profile and minimize channeling effects. In various embodiments, the ion implanted regions 440 with implanted sulfur may experience enhanced etch rates due to the catalytic effect of sulfur ions as described above.

FIG. 4B shows a first etching process by exposing the substrate 100 to a first plasma 42. In various embodiments, the first plasma 42 may be generated from etching gases comprising fluorine-containing gases such as fluorine, nitrogen fluoride, hydrogen fluoride, fluorocarbon, or the like. In various embodiments, the fluorocarbon may comprise the compounds as described previously with reference to FIG. 1C. The conditions and components used during the first etching process may be same with the plasma etching process as described in FIGS. 1C-1D. The first etching process may remove the ion implanted regions 440 through the openings 132.

FIG. 4C shows a second etching process following the first etching process to further etch the layer to-be-etched 120 through the openings 132 in the patterned mask layer 130. In various embodiments, the second plasma 44 used during the second etching process may be generated from a gas mixture comprising sulfur fluoride such as SF₆. In various embodiments, the conditions and processes to generate the second plasma 44 may be same with those to generate the plasma 12 as described with reference to FIG. 1C.

In this partial implantation approach, the selective placement of sulfur catalyst in only the upper portion enables the use of non-SF₆ plasma chemistry during the initial etching phase, reducing the consumption of high global warming potential gases. In various embodiments, the absence of SF₆ at the beginning of etching process helps reduce unwanted profile distortions such as bowing and undercut, which is particularly critical in the upper portion of the etched features where such profile distortions typically initiate.

In various embodiments, between the first and the second etching processes shown in FIGS. 4B and 4C, various intermediate processes may be performed to ensure optimal transition between the two etching steps. In various embodiments, the process chamber may undergo a purge process using inert gases such as argon, helium, or nitrogen to remove residual non-SF₆ process gases and etch byproducts. The purge process may be performed while maintaining vacuum conditions to prevent atmospheric exposure. In an embodiment, the chamber walls and components may be cleaned or conditioned to remove deposits that could affect the subsequent SF₆ etching step. The substrate temperature may be adjusted between the two etching steps to optimize each etch chemistry's performance. In various embodiments, the transition between etch chemistries may include stabilization steps where gas flows and plasma conditions are gradually adjusted to ensure process stability. The RF power and pressure parameters may be ramped to new values suitable for the SF₆ etching step rather than abruptly changed. These intermediate processes help maintain process control and ensure reproducible results during the transition between different etch chemistries.

FIGS. 5A-5E illustrate cross sectional views of another process flow for sulfur ion implantation followed by plasma etching, in accordance with an embodiment. The process illustrated in FIGS. 5A-5E may achieve different etch rates through selective sulfur implantation. Components and features in FIGS. 5A-5E that share reference numbers with those in FIGS. 1A-1D have corresponding structures and operations as previously described.

In FIG. 5A, a substrate 500 may be loaded into a process chamber which may comprise the components and structures of the process chamber described with reference to FIG. 1A. In various embodiments, the substrate 500 may comprise the substrate layer 110, the layer to-be-etched 120 disposed over the substrate layer 110, and a first patterned mask layer 530 disposed over the layer to-be-etched 120. The first patterned mask layer 530 may be formed using similar materials and fabrication methods as described for the patterned mask layer 130 in FIG. 1A. In various embodiments, the first patterned mask layer 530 may comprise metal oxide resist, organic photoresist materials, silicon oxide, silicon nitride, or other suitable masking materials.

The first patterned mask layer 530 may comprise a first opening 532, which may be formed through lithography and etching processes as previously described. In various embodiments, a pattern of the first patterned mask layer 530 may be formed by depositing a mask material over the layer to-be-etched 120, followed by photolithography patterning. In one embodiment, the first patterned mask layer 530 may comprise metal oxide resist, the pattern may be formed using electron beam lithography or extreme ultraviolet lithography, with subsequent development using wet, dry, or plasma development processes. In another embodiment, the first patterned mask layer 530 may comprise organic photoresist, the pattern may be formed through exposure to ultraviolet radiation through a photomask, followed by development in appropriate solutions.

FIG. 5B illustrates an ion implantation process performed by exposing the substrate 500 to an ion flux 50 at a first beam energy through the first opening 532 into the first patterned mask layer 530. Implanting ions may form a first ion implanted region 540 in the layer to-be-etched 120. The ion flux 50 may comprise various types of ions as described for the ion flux 10 in FIG. 1B. In an embodiment, the ion flux 50 may comprise sulfur ions generated from source materials such as solid sulfur, hydrogen sulfide (H₂S), or sulfur fluoride compounds.

The ion implantation system and components used for generating and directing the ion flux 50 may be similar or identical to those described for the ion implantation process in FIG. 1B. In various embodiments, the system may include an ion source for generating sulfur ions, an acceleration column for directing the ions toward the substrate, and a substrate holder for supporting and positioning the substrate 500. In one or more embodiments, the implantation parameters such as ion energy, ranging from 10 keV to 200 keV, and dose, ranging from 10¹⁴ to 10¹⁶ ions/cm², may be controlled to achieve desired implant profiles.

In some embodiments, the ion implantation process in FIG. 5B may utilize a plurality of implants (or staged implantation) similar to that described in FIGS. 3A-3C. The plurality of implants may be performed with different beam energies and doses to create a graded concentration profile in the first implanted region 540. The staged implantation may provide enhanced control over the depth distribution and concentration of implanted ions, enabling optimization of subsequent etch characteristics.

In various embodiments, the ion flux 50 may be implanted into the exposed portions of the layer to-be-etched 120 through the first opening 532, forming the first ion implanted region 540. In various embodiments, the first patterned mask layer 530 may block the ions from reaching covered portions of the layer to-be-etched 120, resulting in selective formation of the first implanted region 540. The first implanted region 540 may serve as a catalytic region that will enhance subsequent etching processes through mechanisms previously described.

FIG. 5C illustrates the formation of a second patterned mask layer 550 over the layer to-be-etched 120, where the second patterned mask layer 550 may comprise the first opening 532 and a second opening 534. In one or more embodiments, the process of forming the second patterned mask layer 550 may preserve the first opening 532 and protect the previously formed first ion implanted region 540.

In various embodiments, the process may begin with applying a photoresist layer over the first patterned mask layer 530. The photoresist layer may cover the first opening 532. Afterwards, a photolithography process may be performed to pattern the photoresist layer. In various embodiments, the photoresist layer may be exposed to create a pattern that exposes a portion of the first patterned mask layer 530 where the second opening 534 will be formed, while maintaining photoresist coverage over the first opening 532 and surrounding areas. After developing the exposed photoresist, an etching process may be performed on the exposed portion of the first patterned mask layer 530 to form the second patterned mask layer 550. In various embodiments, the etching process may comprise dry etching, wet etching, or a combination thereof, selected to achieve desired profile control. Following the formation of the second patterned mask layer 550, the remaining photoresist layer may be removed using appropriate stripping processes. In various embodiments, the photoresist removal is performed before subsequent plasma etching steps to prevent contamination or interference with the etching process.

In accordance with one embodiment, FIG. 6 illustrates a second ion implantation process after forming the second patterned mask layer 550 and before etching the layer to-be-etched 120. In various embodiments, the substrate 500 may be exposed to a second ion flux 60 at a second beam energy, which may comprise ions similar to the first ion implantation process. The second ion implantation process may form a second ion implanted region 642 in the layer to-be-etched 120 through the second opening 534. The second ion implantation process may modify the first ion implanted region 540 with additional sulfur ions. In various embodiments, the first ion implanted region 540 may extend to a first depth from a surface of the layer to-be-etched 120, while the second ion implanted region 642 may extend to a second depth from the surface of the layer to-be-etched 120, where the second depth may be less than the first depth. In various embodiments, the first and the second ion implanted regions 540 and 642 are not overlapped.

In alternative embodiments, the second ion implantation process may be performed while the photoresist layer used to form the second patterned mask layer 550 remains in place. In one embodiment, the second opening 534 may be formed while the photoresist layer may cover the first opening 532. The second ion flux 60 may only reach the layer to-be-etched 120 through the second opening 534, forming the second ion implanted region 642 while the first ion implanted region 540 remain protected and unchanged. This approach enables independent control of implant profiles through different openings, without affecting the previously implanted regions.

FIG. 5D shows a plasma etching process by exposing the substrate 500 to a plasma 52. In various embodiments, the plasma 52 may be generated from etching gases comprising fluorine-containing gases such as fluorine, nitrogen fluoride, hydrogen fluoride, fluorocarbon, or the like. The conditions and components used during the plasma etching process may be same with the etching process as described in FIG. 1D.

In various embodiments, the plasma etching process may etch the layer to-be-etched 120 through a pattern (e.g., the first and the second openings 532 and 534) of the second patterned mask layer 550. In one or more embodiments, the etching rate of the layer to-be-etched 120 through the first opening 532 may be higher than through the second opening 534. The higher etch rate benefits from the sulfur ions in the first ion implanted region 540 that catalyze the reaction between fluorine species and silicon, leading to accelerated material removal.

FIG. 5E illustrates the structure after the plasma etching process reaches the targeted etch depths in the layer to-be-etched 120. In some embodiments, the feature formed through the first opening 532 may reach a deeper depth due to the enhanced etch rate in the first ion implanted region 540, while the feature through the second opening 534 may have a shallower depth. Through the controlled differential etching enabled by selective sulfur implantation, features with different depths may be formed simultaneously, reducing process complexity compared to traditional multiple-step etch processes.

In various embodiments, the plasma etching process may be monitored using endpoint detection techniques to determine when targeted depths are reached. In various embodiments, optical emission spectroscopy, laser interferometry, or other monitoring methods may be employed to track the etch progression.

FIG. 7 illustrates a flow diagram of a method for etching a substrate using sulfur ion implantation, in accordance with an embodiment.

At block 710, a substrate is loaded into a process chamber. The substrate may be the substrate 100 as described with reference to FIG. 1A, comprising the substrate layer 110, the layer to-be-etched 120, and the patterned mask layer 130. As described in reference to FIG. 1A, the patterned mask layer 130 may comprise various materials including metal oxide resist or organic photoresist materials, with openings 132 formed through lithography processes.

At block 720, the layer to-be-etched is implanted through openings in the patterned mask layer. This process corresponds to the ion implantation process shown in FIG. 1B, where sulfur ions are implanted to form implanted regions 140. As described in reference to FIGS. 1B and 3A-3C, the implantation may utilize sulfur-containing source materials such as solid sulfur, hydrogen sulfide (H₂S), or sulfur fluoride compounds, with beam energies between 10 keV to 200 keV. In various embodiments, the implantation may follow the multi-stage approach illustrated in FIGS. 3A-3C to create graded concentration profiles.

At block 730, a plasma is generated from a gas mixture comprising fluorine in the process chamber. This corresponds to the plasma generation process described with reference to FIG. 1C, where gases such as fluorine, nitrogen fluoride, hydrogen fluoride, fluorocarbon, or other fluorine-containing gases are used.

At block 740, the substrate is exposed to the plasma to etch the implanted region through the openings in the patterned mask layer. This etching process corresponds to the initial etching shown in FIG. 1C, where the implanted sulfur catalyzes the reaction between fluorine species and silicon, enhancing the etch rate as demonstrated by the data in FIGS. 2A-2C. In some embodiments, the etching process may utilize different plasma chemistries as detailed in reference to FIGS. 4B-4C.

At block 750, etching of the layer to-be-etched continues until targeted etching depth is reached. This corresponds to the continued etching process shown in FIG. 1D or 4C, where the enhanced etch rate in sulfur-implanted regions enables controlled material removal.

FIG. 8 illustrates a flow diagram of a method for achieving differential etch rates through selective ion implantation, in accordance with an embodiment.

At block 810, a substrate is loaded into a process chamber. The substrate may be the substrate 500 as described with reference to FIG. 5A, comprising the layer to-be-etched 120 and the first patterned mask layer 530. As described in reference to FIG. 5A, the first patterned mask layer 530 may comprise similar materials as the patterned mask layer 130, including metal oxide resist or organic photoresist materials formed through lithography processes.

At block 820, ions are implanted into the layer to-be-etched through the first opening in the first patterned mask layer. This process corresponds to the ion implantation process shown in FIG. 5B, where ions (such as sulfur ions) are implanted to form the first implanted region 540. As described in reference to FIG. 5B, the implantation system and parameters may be similar to those described for earlier embodiments, with beam energies between 10 keV to 200 keV and doses between 10¹⁴ to 10¹⁶ ions/cm².

At block 830, a second patterned mask layer is formed from the first patterned mask layer. This modification process corresponds to the mask modification step shown in FIG. 5C, where a second opening 534 is formed while maintaining the first opening 532. As detailed in reference to FIG. 5C, this process may involve applying the photoresist layer, patterning it to expose portions of the first patterned mask layer while protecting the first opening, etching to form the second patterned mask layer, and removing the photoresist layer.

At block 840, a plasma is generated from a gas mixture comprising fluorine in the process chamber. This corresponds to the plasma generation process described with reference to FIG. 5D, where gases such as fluorine, nitrogen fluoride, hydrogen fluoride, fluorocarbon, or other fluorine-containing gases with lower global warming potential are used to generate reactive fluorine species.

At block 850, the substrate is exposed to the plasma to etch the layer to-be-etched through the pattern in the second patterned mask layer. This etching process corresponds to the initial etching shown in FIG. 5D, where different etch rates are observed through the first opening and the second opening. As described in reference to FIG. 6, in some embodiments, additional implantation may be performed through the second opening before etching.

At block 860, etching of the layer to-be-etched continues until targeted etching depth is reached. This corresponds to the continued etching process shown in FIG. 5E, where the differential etch rates result in features with different depths formed simultaneously. As described in reference to FIG. 5E, this approach enables precise control over relative feature depths without requiring multiple etch steps.

It should be understood that the flow diagrams presented in FIGS. 7 and 8 illustrate simplified process sequences, and various additional steps may be incorporated between the illustrated blocks or as modifications to the illustrated processes. In various embodiments, additional processes not explicitly shown in the flow diagrams may be performed, such as the thermal annealing step after implantation described in reference to FIGS. 1B and 1C, or the multi-stage implantation approach illustrated in FIGS. 3A-3C. Intermediate processes such as chamber purging, cleaning, or conditioning steps may be performed between the blocks shown. In some embodiments, the substrate may be transferred between different process chambers for implantation and etching steps rather than using a single process chamber with dual-mode capacities as described. Additionally, various in-situ monitoring or endpoint detection steps may be incorporated during the etching processes. The flow diagrams represent general process sequences that may be modified with these and other variations while remaining within the scope of the disclosed embodiments.

Although sulfur ions are described in various embodiments, other ion species may be used either as alternatives to or in combination with sulfur ions to achieve enhanced etching effects. In various embodiments, the ion implantation may utilize halogen ions such as chlorine, bromine, or iodine; alkali metals such as sodium or potassium; transition metals such as titanium, tungsten, or molybdenum; or other elements capable of catalyzing silicon etching reactions. These alternative ion species may be implanted individually or co-implanted with sulfur to create customized catalytic effects. In an embodiment, different combinations of ion species may be used to optimize specific aspects of the etching process such as etch rate, selectivity, or profile control. The selection of ion species may be based on factors including ionic radius, chemical reactivity, diffusion characteristics, and compatibility with subsequent processing steps. The implantation parameters for each ion species may be independently controlled to achieve desired concentration profiles and catalytic effects.

In various embodiments, while fluorine-based chemistries are primarily described to generate plasma for etching process, the sulfur catalytic effect may enhance etching processes using other halogen-based chemistries. In various embodiments, the implanted sulfur may catalyze reactions with chlorine-based plasmas generated from gases such as chlorine (Cl₂), boron trichloride (BCl₃), or silicon tetrachloride (SiCl₄); bromine-based plasmas from hydrogen bromide (HBr) or bromine (Br₂); or iodine-containing etch chemistries. The halogen-based etch gases may be used individually or in combinations to optimize etch characteristics. In various embodiments, the etch chemistry may include hydrogen halides (HF, HCl, HBr, HI), interhalogen compounds (ClF₃, BrF₃, IF₅), or mixtures with inert gases such as argon, helium, or nitrogen. The catalytic mechanism of implanted sulfur may facilitate the formation and desorption of volatile silicon-halogen compounds, potentially enhancing etch rates and selectivity across different halogen chemistries. The selection of specific halogen chemistry may depend on factors such as etch rate requirements, material selectivity, environmental considerations, and compatibility with the overall process integration scheme.

Example embodiments of the invention are described below. Other embodiments can also be understood from the entirety of the specification as well as the claims filed herein.
Example 1. A method for etching a substrate, the method including: loading a substrate in a process chamber, the substrate includes a patterned mask layer disposed over a layer to-be-etched; implanting ions into the layer to-be-etched through openings in the patterned mask layer to form an implanted region; after the implanting, generating a plasma including fluorine; and exposing the substrate to the plasma to etch the implanted region.
Example 2. The method of example 1, where the plasma is generated from a gas mixture including fluorine, nitrogen fluoride, hydrogen fluoride, or fluorocarbon.
Example 3. The method of one of examples 1 or 2, where the implanting includes: performing a plurality of implants at different beam energies to form a graded implanted ion concentration profile in the layer to-be-etched.
Example 4. The method of one of examples 1 to 3, further including: transferring the substrate from the process chamber to an etching chamber after the implanting and before generating the plasma.
Example 5. The method of one of examples 1 to 4, where the implanting includes: introducing a sulfur-containing source material into an ion source, where the sulfur-containing source material includes solid sulfur, hydrogen sulfide, or sulfur fluoride; ionizing the sulfur-containing source material to generate sulfur ions; and accelerating the sulfur ions toward the substrate through an acceleration column.
Example 6. The method of one of examples 1 to 5, where the layer to-be-etched includes silicon.
Example 7. The method of one of examples 1 to 6, further including: performing a thermal annealing process after the implanting and before generating the plasma.
Example 8. A method for etching a substrate, the method including: exposing a substrate to ion implantation, the substrate including a patterned mask layer disposed over a layer to-be-etched, and the ion implantation forming an ion implanted region in the layer to-be-etched through openings in the patterned mask layer; performing a first etching process by exposing the ion implanted regions to a first plasma; and after the first etching process, performing a second etching process by exposing the layer to-be-etched to a second plasma, where the second etching process further etches the layer to-be-etched through the openings in the patterned mask layer.
Example 9. The method of example 8, where the first plasma is generated from a gas mixture including fluorine, nitrogen fluoride, hydrogen fluoride, or fluorocarbon.
Example 10. The method of one of examples 8 or 9, where the second plasma is generated from a gas mixture including sulfur fluoride.
Example 11. The method of one of examples 8 to 10, where exposing the substrate to ion implantation includes: performing a plurality of implants at different beam energies to form a graded implanted ion concentration profile in the ion implanted region.
Example 12. The method of one of examples 8 to 11, where exposing the substrate to ion implantation includes: introducing a sulfur-containing source material into an ion source, where the sulfur-containing source material includes solid sulfur, hydrogen sulfide, or sulfur fluoride; ionizing the sulfur-containing source material to generate sulfur ions; and accelerating the sulfur ions toward the substrate through an acceleration column.
Example 13. The method of one of examples 8 to 12, where the layer to-be-etched includes silicon.
Example 14. A method for etching a substrate, the method including: loading a substrate in a process chamber, the substrate includes a first patterned mask layer disposed over a layer to-be-etched; implanting ions at a first beam energy into the layer to-be-etched to form a first ion implanted region; forming a second patterned mask layer over the layer to-be-etched; generating a plasma including fluorine; and exposing the layer to-be-etched to the plasma to etch the first ion implanted region through the second patterned mask layer.
Example 15. The method of example 14, where during exposing the layer to-be-etched to the plasma: the first ion implanted region etches at a higher rate compared to other non-implanted regions in the layer to-be-etched.
Example 16. The method of one of examples 14 or 15, where the plasma is generated from a gas mixture including fluorine, nitrogen fluoride, hydrogen fluoride, or fluorocarbon.
Example 17. The method of one of examples 14 to 16, where forming the second patterned mask includes: applying a photoresist layer over the first patterned mask layer; patterning the photoresist layer to expose a portion of the first patterned mask layer; etching the exposed portion of the first patterned mask layer to form the second patterned mask layer; and removing the photoresist layer before exposing the layer to-be-etched to the plasma.
Example 18. The method of one of examples 14 to 17, where the implanting includes: introducing a sulfur-containing source material into an ion source, where the sulfur-containing source material includes solid sulfur, hydrogen sulfide, or sulfur fluoride; ionizing the sulfur-containing source material to generate sulfur ions; and accelerating the sulfur ions toward the substrate through an acceleration column.
Example 19. The method of one of examples 14 to 18, further including: after forming the second patterned mask layer and before generating the plasma, implanting ions at a second beam energy into the layer to-be-etched to form a second ion implanted region.
Example 20. The method of one of examples 14 to 19, where: the first ion implanted region extends to a first depth from a surface of the layer to-be-etched; the second ion implanted region extends to a second depth from the surface of the layer to-be-etched; and the second depth is less than the first depth.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-8 may be combined in further embodiments. It is therefore intended that the appended claims encompass any such modifications or embodiments.

What is claimed is:

1. A method for etching a substrate, the method comprising:
loading a substrate in a process chamber, the substrate comprises a patterned mask layer disposed over a layer to-be-etched;
implanting ions into the layer to-be-etched through openings in the patterned mask layer to form an implanted region;
after the implanting, generating a plasma comprising fluorine; and
exposing the substrate to the plasma to etch the implanted region.

2. The method of claim 1, wherein the plasma is generated from a gas mixture comprising fluorine, nitrogen fluoride, hydrogen fluoride, or fluorocarbon.

3. The method of claim 1, wherein the implanting comprises:
performing a plurality of implants at different beam energies to form a graded implanted ion concentration profile in the layer to-be-etched.

4. The method of claim 1, further comprising:
transferring the substrate from the process chamber to an etching chamber after the implanting and before generating the plasma.

5. The method of claim 1, wherein the implanting comprises:
introducing a sulfur-containing source material into an ion source, wherein the sulfur-containing source material comprises solid sulfur, hydrogen sulfide, or sulfur fluoride;
ionizing the sulfur-containing source material to generate sulfur ions; and
accelerating the sulfur ions toward the substrate through an acceleration column.

6. The method of claim 1, wherein the layer to-be-etched comprises silicon.

7. The method of claim 1, further comprising:
performing a thermal annealing process after the implanting and before generating the plasma.

8. A method for etching a substrate, the method comprising:
exposing a substrate to ion implantation, the substrate comprising a patterned mask layer disposed over a layer to-be-etched, and the ion implantation forming an ion implanted region in the layer to-be-etched through openings in the patterned mask layer;
performing a first etching process by exposing the ion implanted regions to a first plasma; and
after the first etching process, performing a second etching process by exposing the layer to-be-etched to a second plasma, wherein the second etching process further etches the layer to-be-etched through the openings in the patterned mask layer.

9. The method of claim 8, wherein the first plasma is generated from a gas mixture comprising fluorine, nitrogen fluoride, hydrogen fluoride, or fluorocarbon.

10. The method of claim 8, wherein the second plasma is generated from a gas mixture comprising sulfur fluoride.

11. The method of claim 8, wherein exposing the substrate to ion implantation comprises:
performing a plurality of implants at different beam energies to form a graded implanted ion concentration profile in the ion implanted region.

12. The method of claim 8, wherein exposing the substrate to ion implantation comprises:
introducing a sulfur-containing source material into an ion source, wherein the sulfur-containing source material comprises solid sulfur, hydrogen sulfide, or sulfur fluoride;
ionizing the sulfur-containing source material to generate sulfur ions; and
accelerating the sulfur ions toward the substrate through an acceleration column.

13. The method of claim 8, wherein the layer to-be-etched comprises silicon.

14. A method for etching a substrate, the method comprising:
loading a substrate in a process chamber, the substrate comprises a first patterned mask layer disposed over a layer to-be-etched;
implanting ions at a first beam energy into the layer to-be-etched to form a first ion implanted region;
forming a second patterned mask layer over the layer to-be-etched;
generating a plasma comprising fluorine; and
exposing the layer to-be-etched to the plasma to etch the first ion implanted region through the second patterned mask layer.

15. The method of claim 14, wherein during exposing the layer to-be-etched to the plasma:
the first ion implanted region etches at a higher rate compared to other non-implanted regions in the layer to-be-etched.

16. The method of claim 14, wherein the plasma is generated from a gas mixture comprising fluorine, nitrogen fluoride, hydrogen fluoride, or fluorocarbon.

17. The method of claim 14, wherein forming the second patterned mask layer comprises:
applying a photoresist layer over the first patterned mask layer;
patterning the photoresist layer to expose a portion of the first patterned mask layer;
etching the exposed portion of the first patterned mask layer to form the second patterned mask layer; and
removing the photoresist layer before exposing the layer to-be-etched to the plasma.

18. The method of claim 14, wherein the implanting comprises:
introducing a sulfur-containing source material into an ion source, wherein the sulfur-containing source material comprises solid sulfur, hydrogen sulfide, or sulfur fluoride;
ionizing the sulfur-containing source material to generate sulfur ions; and
accelerating the sulfur ions toward the substrate through an acceleration column.

19. The method of claim 14, further comprising:
after forming the second patterned mask layer and before generating the plasma, implanting ions at a second beam energy into the layer to-be-etched to form a second ion implanted region.

20. The method of claim 19, wherein:
the first ion implanted region extends to a first depth from a surface of the layer to-be-etched;
the second ion implanted region extends to a second depth from the surface of the layer to-be-etched; and
the second depth is less than the first depth.
